(19) United States
(12) Patent Application Publication
(10) Pub. No.: US 2014/0008772 A1
(43) Pub. Date: Jan. 9, 2014

(54) SEMICONDUCTOR DEVICES AND METHODS OF FABRICATING THE SAME

(71) Applicant: SAMSUNG ELECTRONICS CO., LTD., Suwon-si (KR)

(72) Inventor: Yun-Rae Cho, Hwaseong-si (KR)

(73) Assignee: SAMSUNG ELECTRONICS CO., LTD., Suwon-si (KR)

(21) Appl. No.: 13/803,136

(22) Filed: Mar. 14, 2013

(30) Foreign Application Priority Data
Jul. 6, 2012 (KR) 10-2012-0073955

(51) Int. Cl. H01L 23/552

(52) U.S. Cl. CPC H01L 23/552
USPC 257/659

(57) ABSTRACT

Provided are semiconductor devices and methods of fabricating the same. The semiconductor device may include a wiring board including a mounting region and a ground region that surrounds the mounting region, a ground pad positioned at the ground region, at least one semiconductor chip mounted at the mounting region of the wiring board, a molding layer covering the semiconductor chip and a first surface of the wiring board and exposing a portion of the ground pad of the ground region of the wiring board, and a shield layer covering the molding layer and electrically connected to the ground pad. The molding layer comprises a plurality of light-sensitive particles positioned in the molding layer and a plurality of conductive particles positioned at a surface of the molding layer. The shield layer is in direct contact with the conductive particles.

### CROSS-REFERENCE TO RELATED APPLICATIONS

This U.S. non-provisional patent application claims priority under 35 U.S.C. §119 to Korean Patent Application No. 10-2012-0073955, filed on Jul. 6, 2012, in the Korean Intellectual Property Office, the entire contents of which are hereby incorporated by reference.

### FIELD OF THE INVENTION

Embodiments of the inventive concepts relate to semiconductor devices and methods of fabricating the same, and in particular, to semiconductor devices having a shielding element and methods of fabricating the same.

### BACKGROUND

There is a growing trend to fabricate lightweight, small-sized, high speed, multifunctional, high performance, and low-cost electronic systems. In response to such a trend, multi-chip stacked package techniques and/or system in package techniques may have been proposed.

In a multi-chip stacked package or a system in package, one or more semiconductor devices may perform one or more functions in a single semiconductor package. A multi-chip stacked package or a system in package may have a thicker thickness as compared to a single chip package but have a similar size to the single chip package in terms of a planar surface area or ‘footprint’. Thus, a multi-chip stacked package or a system in package may be used in small electronic devices such as mobile devices with high performance requirements, for example, mobile phones, notebook computers, memory cards, and/or portable camcorders.

### SUMMARY

Embodiments of the inventive concepts provide semiconductor devices with improved operating reliability. Other embodiments of the inventive concepts provide methods of fabricating a semiconductor device with improved operating reliability.

According to an aspect of the inventive concepts, provided is a semiconductor device including a wiring board including a mounting region and a ground region that surrounds the mounting region, a ground pad positioned at the ground region, at least one semiconductor chip mounted at the mounting region of the wiring board, a molding layer covering the semiconductor chip and a first surface of the wiring board and exposing a portion of the ground pad of the ground region of the wiring board, and a shield layer covering the molding layer and electrically connected to the ground pad. The molding layer comprises a plurality of light-sensitive particles positioned in the molding layer and a plurality of conductive particles positioned at a surface of the molding layer. The shield layer is in direct contact with the conductive particles.

In an embodiment, the light-sensitive particles comprise a laser direct structure or a light-sensitive polymer.

In an embodiment, the laser direct structure comprises a plurality of metal oxide particles.

In an embodiment, the molding layer has a side surface at an angle with respect to the first surface of the wiring board.

In an embodiment, the at least one semiconductor chip comprises a plurality of semiconductor chips those are stacked according to a step-wise structure.

In an embodiment, the semiconductor chips are of the same kind.

In an embodiment, the wiring board comprises a connection pad provided on a second surface of the wiring board opposite the first surface, and the wiring board further comprises a through electrode extending through the wiring board to connect the ground pad to the connection pad.

According to another aspect of the inventive concepts, provided is a method of fabricating a semiconductor device. The method comprises constructing and arranging a wiring board to include a plurality of mounting regions and a plurality of ground regions. Each of the ground regions surrounds a corresponding mounting region of the plurality of mounting regions and includes at least one ground pad. The ground regions are connected to each other. The method further comprises mounting at least one semiconductor chip on each of the mounting regions, forming a molding layer containing light-sensitive particles to cover the semiconductor chips and a first surface of the wiring board, patterning the molding layer to expose the ground regions, illuminating a light on the molding layer to transform the light-sensitive particles to conductive particles those are positioned at a surface of the molding layer, and forming a shield layer according to a plating process. The conductive particles are used as a seed layer. The shield layer covers the molding layer and is electrically connected to the at least one ground pad.

In an embodiment, the patterning of the molding layer is performed using an infrared laser.

In an embodiment, the patterning of the molding layer is performed in such a way that the molding layer has a side surface at an angle with respect to the first surface of the wiring board.

In an embodiment, the light illuminated on the molding layer includes a carbon-gas laser beam.

In an embodiment, the light-sensitive particles each comprises a laser direct structure or a light-sensitive polymer.

In an embodiment, the method further includes cutting the wiring board along the ground regions to separate the wiring board into individual semiconductor devices.

In an embodiment, the at least one semiconductor chip includes a plurality of semiconductor chips, and the mounting of the at least one semiconductor chip includes stacking the plurality of semiconductor chips to form a step-wise structure.

In an embodiment, the wiring board includes a connection pad provided on a second surface opposite the first surface, and the wiring board further includes a through electrode penetrating the same to connect the at least one ground pad to the connection pad.

According to another aspect of the inventive concept, provided is a semiconductor device, comprising a wiring board having a ground pad at an edge of the wiring board, at least one semiconductor chip on the wiring board, and a molding layer covering the semiconductor chip. The molding layer comprises a plurality of light-sensitive particles and a plurality of conductive particles at a surface of the molding layer. The conductive particles are formed of light-sensitive particles of the plurality of light-sensitive particles. A shield layer covers the molding layer and is electrically connected to the ground pad and the conductive particles at the molding layer.

In an embodiment, the wiring board includes a mounting region and a ground region that surrounds the mounting region, wherein the at least one semiconductor chip is mounted at the mounting region, and wherein the ground pad is at the ground region.

In an embodiment, the wiring board comprises a connection pad and a through electrode that extends through the wiring board to connect the ground pad to the connection pad.

In an embodiment, a combination of the shield layer electrically connected to the ground pad and the conductive particles, the ground pad at the edge of the wiring board, the through electrode connected to the ground pad, and the connection pad connected to the through electrode is constructed and arranged to prevent the device from an electromagnetic field.

In an embodiment, the at least one semiconductor chip comprises a plurality of semiconductor chips those are stacked according to a step-wise structure.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a sectional view illustrating a semiconductor device according to embodiments of the inventive concept.

FIGS. 2 through 7 are sectional views illustrating a method of fabricating a semiconductor device according to embodiments of the inventive concept.

FIGS. 8A through 8C are enlarged views illustrating portions of FIGS. 4 through 6, respectively.

FIG. 9 is a plan view illustrating a package module according to embodiments of the inventive concept.

FIG. 10 is a block diagram illustrating a memory card in accordance with embodiments of the inventive concept.

FIG. 11 is a block diagram illustrating an electronic system in accordance with embodiments of the inventive concept.

FIG. 12 is a perspective diagram illustrating an electronic apparatus in accordance with embodiments of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations those are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

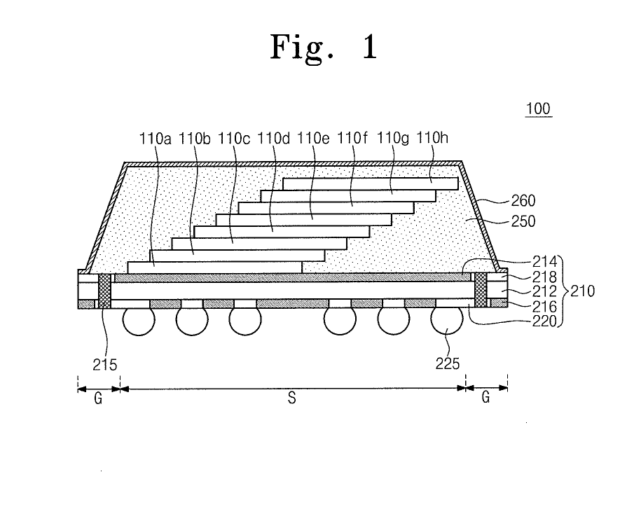

FIG. 1 is a sectional view illustrating a semiconductor device according to example embodiments of the inventive concept.

Referring to FIG. 1, a semiconductor device 100 may include stacked semiconductor chips 110a, 110b, 110c, 110d, 110e, 110f, 110g, and 110h (generally, 110), a wiring board 210, a molding layer 250, and a shield layer 260.

A stack of the semiconductor chips 110a-110h may be constructed and arranged to have a step-wise structure. In some embodiments, the semiconductor chips 110a-110h are similar or of the same kind. The semiconductor chips 110a-110h may be stacked with an attaching layer (not shown) interposed therebetween. The stack of the semiconductor chips 110a-110h may be mounted on the wiring board 210 with an attaching layer interposed therebetween.

The semiconductor chips 110a-110h may be electrically connected to each other using bonding wires or related electrically conductive devices (not shown). At least one of the semiconductor chips 110a-110h may be electrically connected to the wiring board 210 by at least one bonding wire or related electrically conductive device. Embodiments of the inventive concept are not limited to the illustrated example shown in FIG. 1, i.e., in which the semiconductor chips 110a-110h are stacked to form the step-wise structure. Although not shown, a stacking structure of the semiconductor chips 110a-110h may be variously modified. Further, the semiconductor device 100 may be configured to include one semiconductor chip 110, instead of a stacked structure of multiple semiconductor chips 110.

The wiring board 210 may include a mounting region S and a ground region G. In some embodiments, the ground region G at least partially or completely surrounds the mounting region S. For example, the mounting region S may correspond to a central portion of the wiring board 210, and the ground region G may correspond to a circumferential region of the wiring board 210 surrounding the mounting region S.

The wiring board 210 may include a core material 212 serving as a body thereof, an upper insulating layer pattern 214 provided with ground pads 218, and a lower insulating layer pattern 216 provided with connection pads 220. The ground pads 218 and the connection pads 220 may be connected to a circuit pattern (not shown) provided in the core material 212. The ground pads 218 and the connection pads 220 may include copper (Cu) or related material. The ground pads 218 may constitute a portion of an upper surface of the ground region G of the wiring board 210. The semiconductor chips 110a-110h may be mounted on an upper surface of the mounting region S of the wiring board 210.

The wiring board 210 may be a printed circuit board (PCB). The ground pads 218 of the ground region G of the wiring board 210 may be electrically connected to the shield layer 260. Solder balls 225 may be formed on the connection pads 220 of the wiring board 210 to provide conductive paths to an external circuit. The wiring board 210 may further include a through electrode 215 penetrating the same and connecting the ground pad 218 to the connection pad 220. The through electrode 215 may include copper or the like.

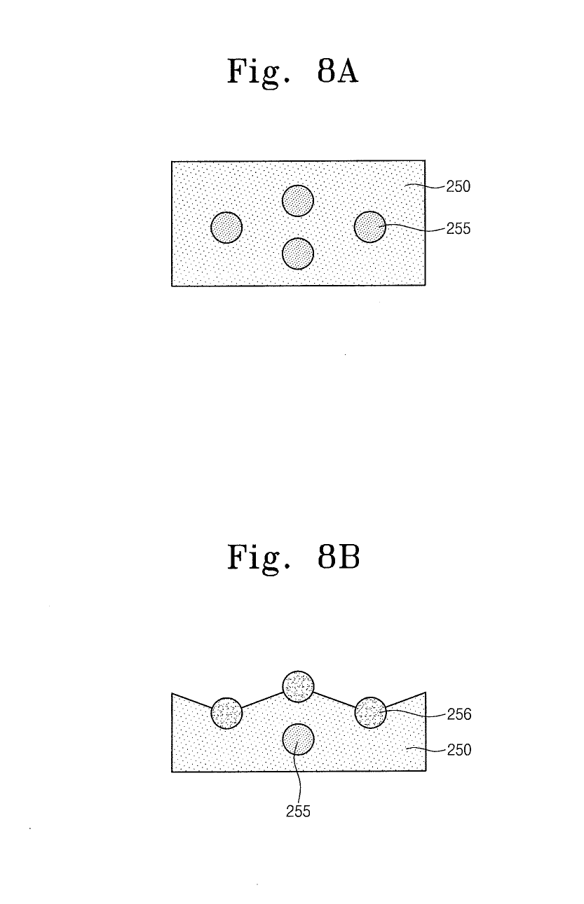

The molding layer 250 may cover the semiconductor chips 110a-110h and the upper surface of the wiring board 210. In some embodiments, the ground pads 218 of the ground region G of the wiring board 210 may be partially exposed by the molding layer 250. The molding layer 250 may include light-sensitive particles, e.g., particles 255 shown and described with respect to FIG. 8A provided therein and conductive particles, e.g., particles 256 shown and described with respect to FIG. 8B or 8C provided on a surface thereof. The light-sensitive particles may be formed of a material that exhibits an electrically insulating property in a normal state and an electrically conductive property under the presence of light incident thereto. The light-sensitive particles may be configured to include a laser direct structure (LDS) or a light-sensitive polymer. The laser direct structure may include metal oxide particles. The molding layer 250 may include an epoxy molding compound (EMC). The molding layer 250 may have a sidewall extending at an angle to the upper surface of the wiring board 210.

The shield layer 260 may cover the molding layer 250. The shield layer 260 may be electrically connected to the ground pads 218 of the ground region G, which are exposed by the molding layer 250. The shield layer 260 may include a metallic material, such as copper. The shield layer 260 may be formed by a plating process, in which the conductive particles from the molding layer 250 may be used as a seed layer. For example, the light-sensitive particles in the molding layer 250 may be exposed by a light that is incident thereto, thereby serving as the seed layer of the plating process. Accordingly, the shield layer 260 may be in direct contact with the conductive particles.

An electromagnetic interference (EMI) may result from radiated emission (RE) or conducted emission (CE) in electronic devices and result in malfunction and deterioration in performance of electronic devices adjacent thereto.

According to some embodiments of the inventive concept, the semiconductor device 100 may include the ground pad 218 provided at an edge region of the wiring board 210. Also, the shield layer 260 is electrically connected to the ground pad 218. Also, the through electrode 215 is connected to the ground pad 218, and the connection pad 220 is connected to the through electrode 215. Here, the semiconductor device 100 is prevented from deteriorating due to an external electromagnetic field. In addition, due to the presence of the through electrode 215, the semiconductor device 100 can be prevented from being affected by an external electromagnetic field applied through a side surface of the wiring board 210. For example, even if the stacked semiconductor chips 110a-110h in the semiconductor device 100 may generate an electromagnetic field, a technical problem caused by the electromagnetic interference can be relieved by the arrangement of the ground pad 218, the through electrode 215, the connection pad 220, and the solder ball 225 electrically connected thereto. In addition, the shield layer 260, the ground pad 218, the through electrode 215, the connection pad 220, and the solder ball 225 may collectively contribute to preventing the semiconductor device 100 from deteriorating due to an external electromagnetic field. As a result, it is possible to reduce the semiconductor device 100 from being disadvantageously affected by an internal and/or external electromagnetic interference, and operation reliability of the semiconductor device 100 can be improved.

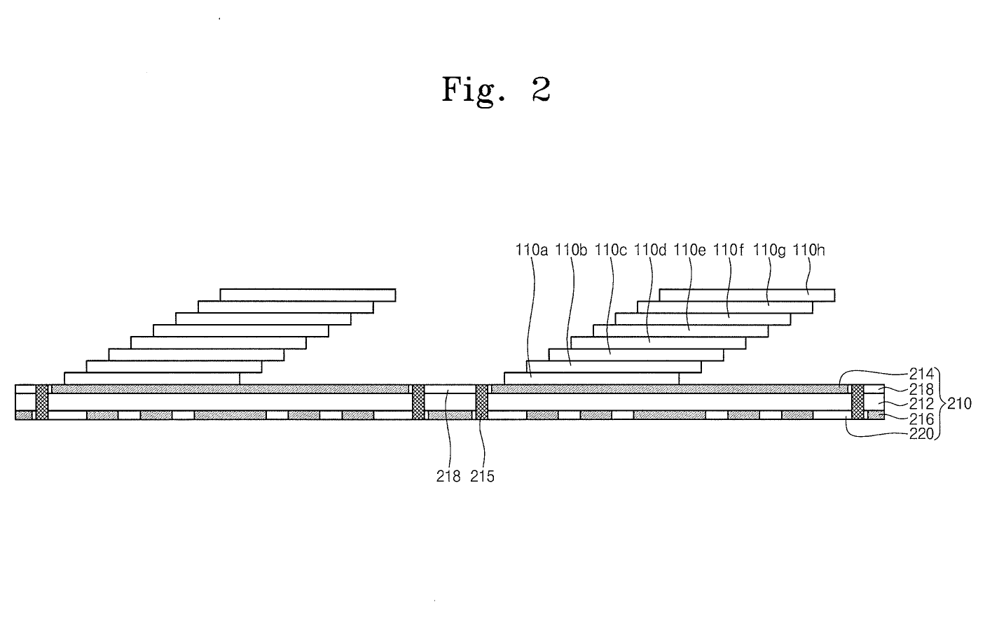

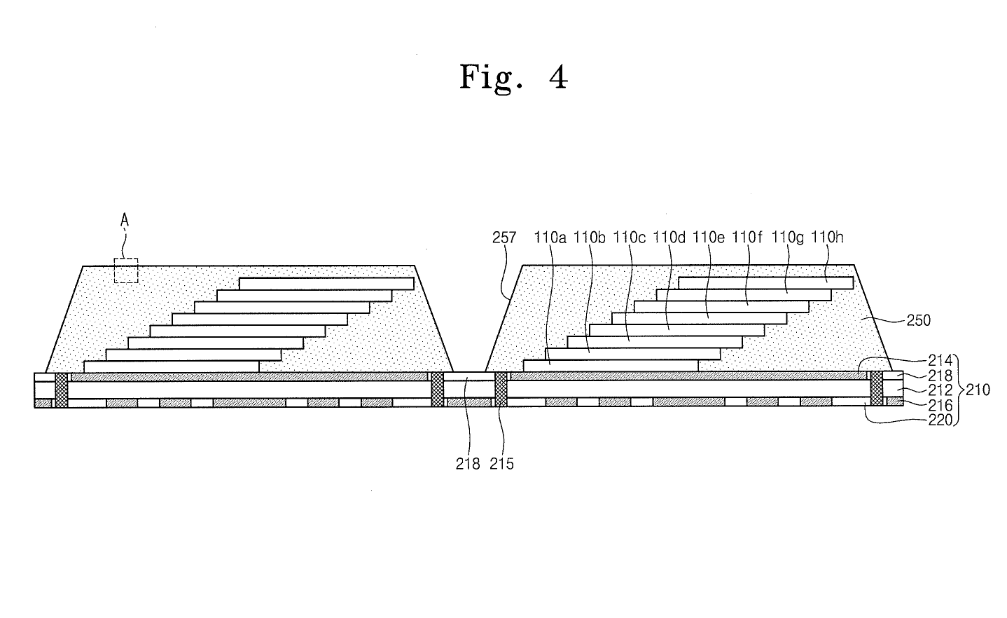

FIGS. 2 through 7 are sectional views illustrating a method of fabricating a semiconductor device according to example embodiments of the inventive concept. FIGS. 8A through 8C are enlarged views illustrating portions A of FIGS. 4 through 6, respectively. In describing FIGS. 2-8C, reference can be made to elements of FIG. 1.

Referring to FIG. 2, a wiring board 210 may be provided to include mounting regions (e.g., mounting region S of FIG. 1) and ground regions (e.g., ground regions G of FIG. 1), each of which surrounds the corresponding one of the mounting regions S, and which are connected to each other. Each of the ground regions G may include at least one ground pad 218.

The wiring board 210 may include a core material 212 as a body thereof, an upper insulating layer pattern 214 including the ground pads 218, and a lower insulating layer pattern 216 including connection pads 220. The ground pads 218 and the connection pads 220 may be connected to circuit patterns (not shown) provided in the core material 212. The ground pads 218 and the connection pads 220 may include a copper. The ground pads 218 may be provided on an upper surface of the ground region of the wiring board 210. Each of semiconductor chips 110a-110h may be mounted on an upper surface of the corresponding one of the mounting regions of the wiring board 210.

The wiring board 210 may include a printed circuit board. The wiring board 210 may further include a through electrode 215 that extends through the wiring board 210 and connects a ground pad 218 with a connection pad 220. The through electrode 215 may include copper or other conductive metal, alloy, or the like.

Each of the semiconductor chips 110a-110h may be mounted on the mounting regions, respectively. The semiconductor chips 110a-110h may be stacked to form a step-wise structure. The semiconductor chips 110a-110h may be of the same or similar kind. The semiconductor chips 110a-110h may be stacked with an attaching layer (not shown) interposed between two or more chips of the semiconductor chips 110a-110h. The stack of semiconductor chips 110a-110h may be mounted on the wiring board 210 with an attaching layer interposed between stack of chips and an upper surface of the wiring board 210.

The semiconductor chips 110a-110h forming the step-wise structure may be electrically connected to each other using bonding wires or the like (not shown). Further, at least one of the semiconductor chips 110a-110h may be electrically connected to the wiring board 210 by at least one bonding wire. Example embodiments of the inventive concept may not be limited to the illustrated example of the present embodiment, in which the semiconductor chips 110a-110h are stacked to form the step-wise structure. Although not shown, a stacking structure of the semiconductor chips 110a-110h may be variously modified. Further, the semiconductor device 100 may be configured to include one semiconductor chip, instead of a plurality of semiconductor chips.

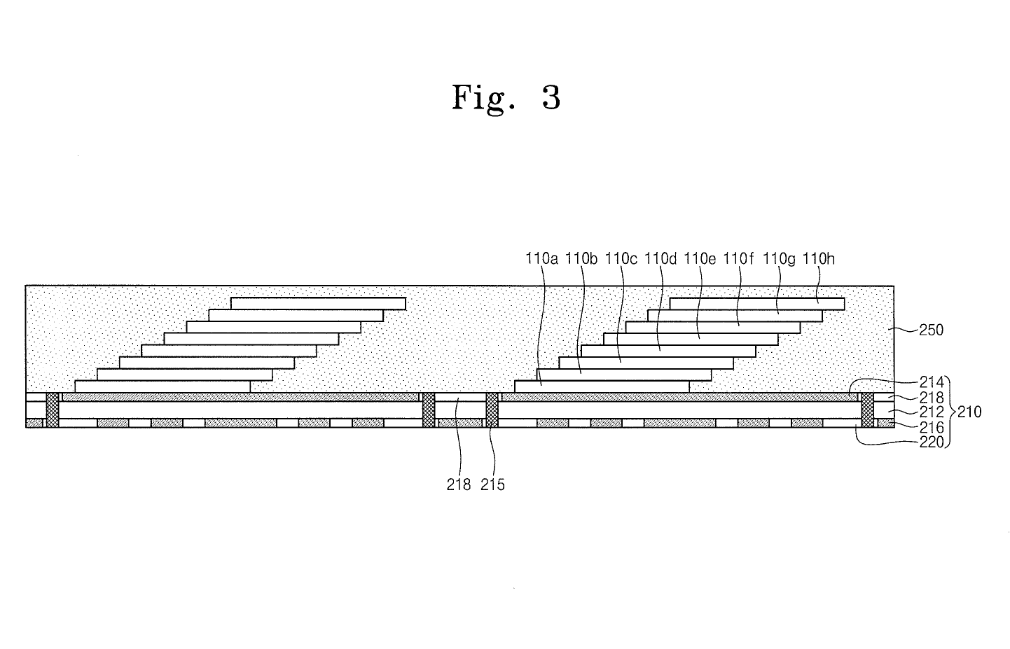

Referring to FIG. 3, a molding layer 250 may be formed to cover the semiconductor chips 110a-110h and an upper surface of the wiring board 210. The molding layer 250 may include light-sensitive particles (for example, particles 255 in FIG. 8A). The light-sensitive particles may comprise a material, which exhibits an insulating property in a normal condition and becomes conductive when a light illuminates thereon. The light-sensitive particles may include a laser direct structure or a photo-sensitive polymer. The laser direct structure may include metal oxide particles. The molding layer 250 may include an epoxy molding compound.

Referring to FIGS. 4 and 8A, the molding layer 250 may be patterned to expose at least partially each of the ground pads 218 of the ground regions of the wiring board 210.

The patterning of the molding layer 250 may include an etching step, in which a laser beam is used expose the ground pads 218. The patterning of the molding layer 250 may be performed, but not limited to, using an infrared (IR) laser.

The molding layer 250 may have a sidewall extending at an angle to the upper surface of the wiring board 210. An opening 257 may be formed between the patterned molding layers 250. The opening 257 may have a ‘V’-shaped configuration. The shape of the opening 257, e.g., a V-shaped opening, may increase a process margin in a subsequent cutting process, which may be performed at the bottom of the opening 257 to separate the wiring board 210 into individual semiconductor devices, and prevent the wiring board 210 from being damaged.

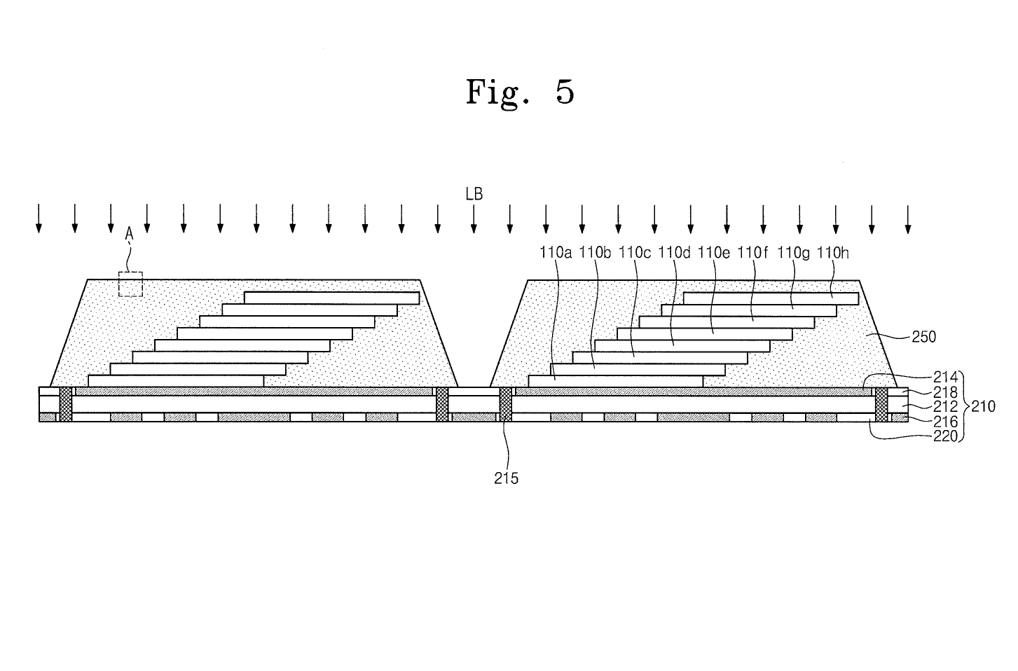

Referring to FIGS. 5 and 8B, a light beam LB may be illuminated on the molding layers 250, such that the light-sensitive particles 255 in the molding layers 250 are transformed to conductive particles 256 and exposed through surfaces of the molding layers 250. As described above, the light-sensitive particles 255 in the molding layers 250 may become conductive, i.e., conductive particles 256, by the illumination of the light beam LB.

Accordingly, the illumination of the light beam LB may cause the transformation from the light-sensitive particles 255 to the conductive particles 256. In addition, the surfaces of the molding layers 250 may be etched as the result of the illumination of the light beam LB. Thus, the conductive particles 256 may be exposed through the surfaces of the molding layers 250. The light beam LB may include, but not be limited to, a carbon-gas (CO₂) laser beam.

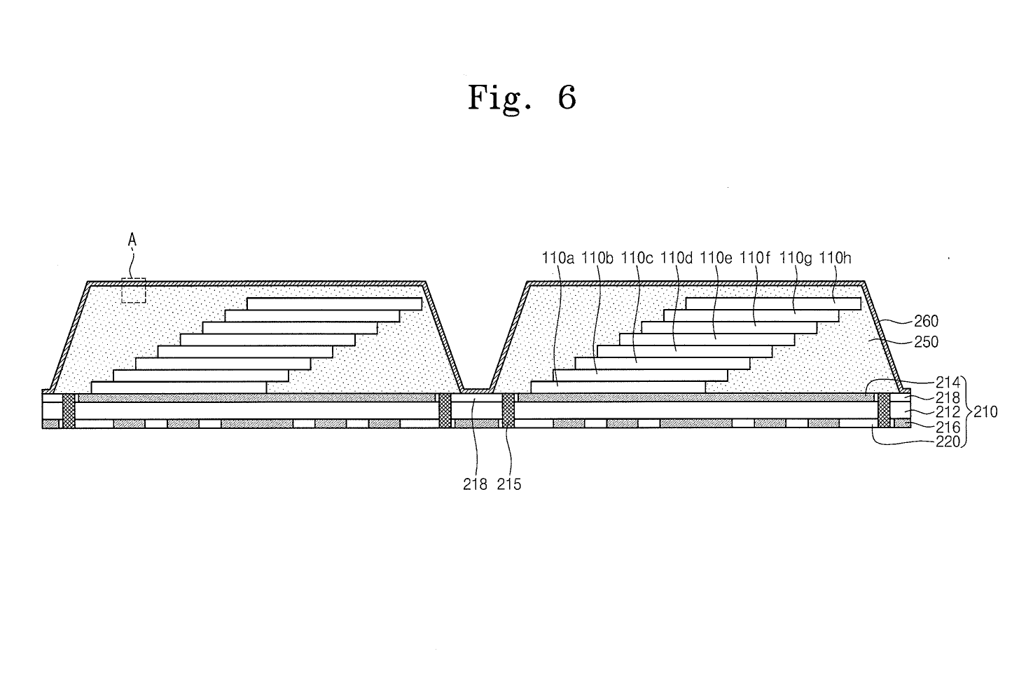

Referring to FIGS. 6 and 8C, a plating process may be performed to form a shield layer 260 covering the molding layers 250. In some embodiments, the conductive particles 256 exposed through the surfaces of the molding layers 250 may be used as a seed layer in the plating process. The shield layer 260 may be electrically connected to the ground pads 218 of the wiring board 210 exposed by the molding layers 250. In other embodiments, the plating process is performed in an electroless plating manner. The shield layer 260 may include a metallic material, such as copper or the like.

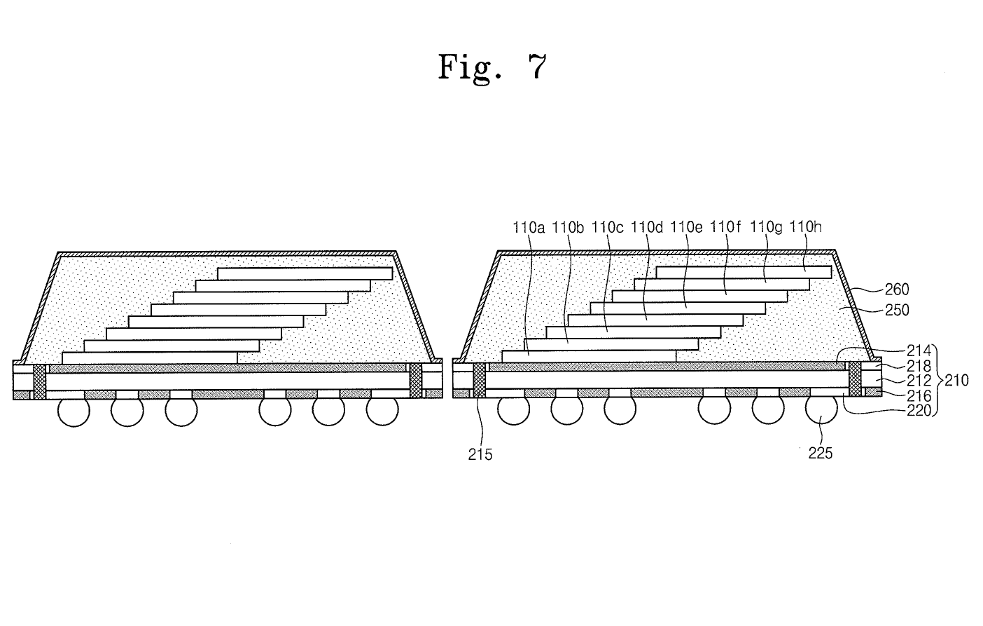

Referring to FIG. 7, a cutting or sawing process may be performed using a cutting or sawing apparatus to cut the ground regions G of the wiring board 210 and separate them into individual semiconductor devices, for example, the semiconductor device 100 of FIG. 1.

Each of the separated semiconductor devices may include a plurality of solder balls 225, which may be coupled to the connection pads 220 of the wiring board 210, respectively. In this manner, the solder balls 225 may serve as electrical paths electrically connecting the semiconductor devices to an external circuit.

Alternatively, the solder balls 225 may be provided on the wiring board 210 in advance. The shield layer 260 may be formed of using the light-sensitive particles, such as particles 255 of FIG. 8A, provided in the molding layer 250. Thus, the semiconductor device may be used to realize both a ball grid array (BGA) shape and a land grid array (LGA) shape.

According to example embodiments of the inventive concept, the semiconductor device may include the ground pad 218 at an edge of the wiring board 210. Also, the shield layer 260 may be electrically connected to the ground pad 218. Also, the through electrode 215 may be connected to the ground pad 218, and the connection pad 220 may be connected to the through electrode 215. Thus, the semiconductor device can be protected against external electromagnetic interference. In addition, due to the presence of the through electrode 215, it is possible to shield an external electromagnetic interference that may otherwise be applied through a side portion of the wiring board 210. In other words, although an electromagnetic interference may be produced from the semiconductor chips 110a-110h, the ground pad 218, the through electrode 215, the connection pad 220, and the solder ball 225 connected thereto can be constructed and arranged to reduce the electromagnetic interference. Further, the shield layer 260, the ground pad 218, the through electrode 215, the connection pad 220 and the solder ball 225 may shield the semiconductor device 100 from external electromagnetic interference, or more importantly, prevent or reduce the risk of damage to the semiconductor device 100 when exposed to external electromagnetic interference. Accordingly, it is possible to suppress the semiconductor device 100 from malfunction by an internal and/or external electromagnetic interference, and thus, the semiconductor device operates with improved reliability.

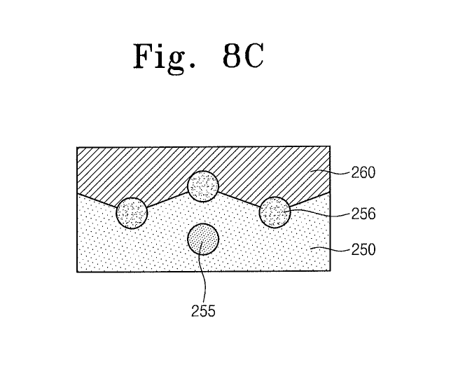

FIG. 9 is a plan view illustrating a package module 700 according to embodiments of the inventive concept.

Referring to FIG. 9, the package module 700 may include a module substrate 702, which may be provided with at least one external connection terminal 708. The package module 700 may further include at least one semiconductor chip 704 and at least one semiconductor package 706, for example, a quad-flat-package (QFP) structure, mounted on the module substrate 702. The semiconductor package 706 may include one or more semiconductor devices according to embodiments of the inventive concept. The package module 700 may be electrically connected to an external electronic device via the external connection terminal 708.

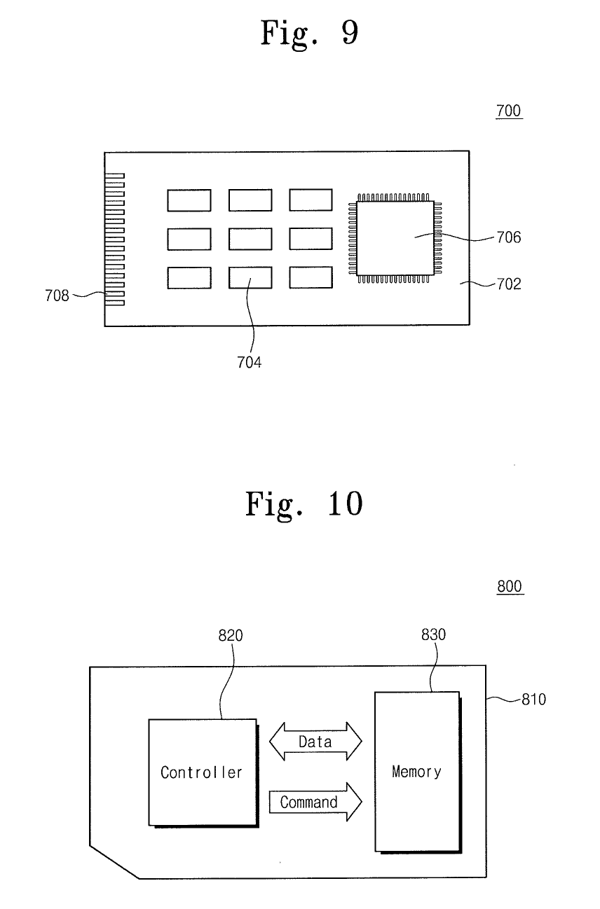

FIG. 10 is a block diagram illustrating a memory card 800 in accordance with embodiments of the inventive concept.

Referring to FIG. 10, the card 800 may include a controller 820 and a memory 830 in a housing 810. The controller 820 and the memory 830 may exchange an electric signal with each other. For example, the memory 830 and the controller 820 may exchange data with each other according to a command provided by the controller 820. Thus, the memory card 800 may store data in the memory 830 or may output data from the memory 830.

The controller 820 and/or the memory 830 may include at least one of the semiconductor devices in accordance with embodiments of the inventive concept, for example, described herein. For example, the controller 820 may include a system in package, and the memory 830 may include a multichip package. The controller 820 and/or the memory 830 may be provided in a stacked package type. The memory card 800 may be used as a data storage medium for various portable devices. For example, the memory card 800 may include a multi media card (MMC) or a secure digital (SD) card.

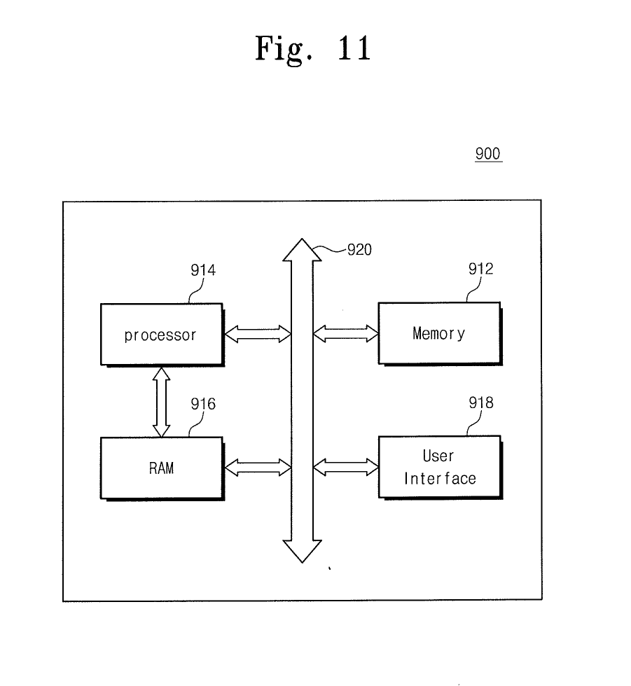

FIG. 11 is a block diagram illustrating an electronic system 900 in accordance with embodiments of the inventive concept.

Referring to FIG. 11, the electronic system 900 may include at least one of the semiconductor devices in accordance with an embodiment of the inventive concept, for example, described herein. The electronic system 900 may include a mobile device or a computer. For example, the electronic system 900 may include a memory system 912, a processor 914, a random access memory (RAM) 916, and a user interface 918 that can exchange data with one another using a bus 920. The processor 914 may execute a program and/or control the electronic system 900. The RAM 916 may be used as an operation memory of the processor 914. For example, the processor 914 and the RAM 916 may include a semiconductor device in accordance with embodiments of the inventive concept. The processor 914 and the RAM 916 may be included in one package. The user interface 918 may be used to input data in the electronic system 900 or to output data from the electronic system 900. The memory system 912 may store program code for performing an operation of the processor 914, data processed by the processor 914, and/or data input from an external source. The memory system 912 may include a controller and a memory, and may be the same as or similar to the memory card 800 of FIG. 10.

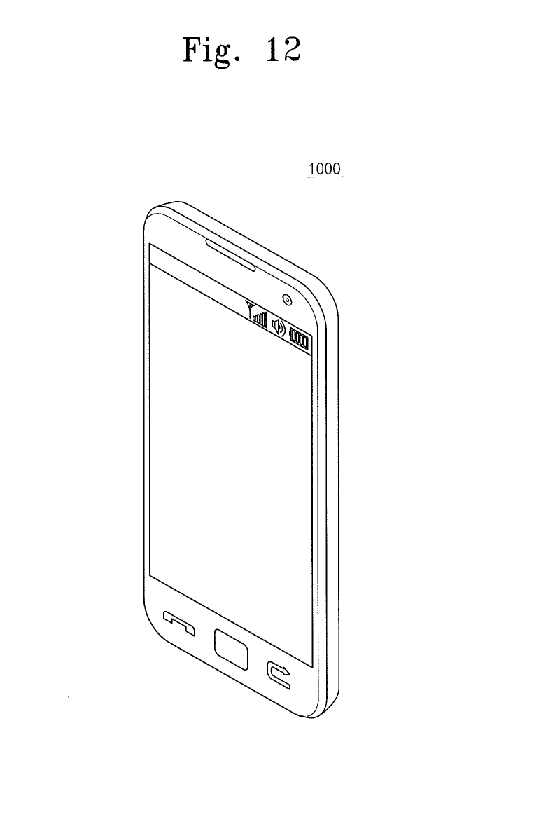

The electronic system 900 may be applied to various electronic devices. For example, as shown in FIG. 12, the electronic system 900 can be applied to a mobile phone 1000. According to other embodiments, the electronic system 900 may be applied to a portable notebook, a MP3 player, a navigation system, a solid state disk (SSD), a vehicle, or home appliances.

According to example embodiments of the inventive concept, the semiconductor device may include a shield layer constituting an exterior surface thereof and protecting the semiconductor device against both of internal and external electromagnetic interferences. Accordingly, a semiconductor device in accordance with embodiments can operate with improved reliability.

According to other embodiments of the inventive concept, the formation of the semiconductor device may include a step of forming the shield layer that can protect the semiconductor device against both internal and external electromagnetic interferences. Accordingly, it is possible to provide a method of fabricating a semiconductor device with improved operating reliability.

While example embodiments of the inventive concepts have been particularly shown and described, it will be understood by one of ordinary skill in the art that variations in form and detail may be made therein without departing from the spirit and scope of the attached claims.

1. A semiconductor device, comprising:
a wiring board including a mounting region and a ground region that surrounds the mounting region;
a ground pad positioned at the ground region;
at least one semiconductor chip mounted at the mounting region of the wiring board;
a molding layer covering the semiconductor chip and a first surface of the wiring board and exposing a portion of the ground pad of the ground region of the wiring board; and
a shield layer covering the molding layer and electrically connected to the ground pad,
wherein the molding layer comprises a plurality of light-sensitive particles positioned in the molding layer and a plurality of conductive particles positioned at a surface of the molding layer, and
wherein the shield layer is in direct contact with the conductive particles.

2. The device of claim 1, wherein the light-sensitive particles comprise a laser direct structure or a light-sensitive polymer.

3. The device of claim 2, wherein the laser direct structure comprises a plurality of metal oxide particles.

4. The device of claim 1, wherein the molding layer has a side surface at an angle with respect to the first surface of the wiring board.

5. The device of claim 1, wherein the at least one semiconductor chip comprises a plurality of semiconductor chips those are stacked according to a step-wise structure.

6. The device of claim 5, wherein the semiconductor chips are of the same kind.

7. The device of claim 1, wherein the wiring board comprises a connection pad provided on a second surface of the wiring board opposite the first surface, and
wherein the wiring board further comprises a through electrode extending through the wiring board to connect the ground pad to the connection pad.

8-15. (canceled)

16. A semiconductor device, comprising:
a wiring board having a ground pad at an edge of the wiring board;
at least one semiconductor chip on the wiring board;
a molding layer covering the at least one semiconductor chip, the molding layer comprising a plurality of light-sensitive particles and a plurality of conductive particles at a surface of the molding layer, the conductive particles formed of light-sensitive particles of the plurality of light-sensitive particles; and
a shield layer covering the molding layer and electrically connected to the ground pad and the conductive particles at the molding layer.

17. The device of claim 16, wherein the wiring board includes a mounting region and a ground region that surrounds the mounting region, wherein the at least one semiconductor chip is mounted at the mounting region, and wherein the ground pad is at the ground region.

18. The device of claim 16, wherein the wiring board comprises a connection pad and a through electrode that extends through the wiring board to connect the ground pad to the connection pad.

19. The device of claim 16, wherein a combination of the shield layer electrically connected to the ground pad and the conductive particles, the ground pad at the edge of the wiring board, the through electrode connected to the ground pad, and the connection pad connected to the through electrode is constructed and arranged to prevent the device from an electromagnetic field.

20. The device of claim 16, wherein the at least one semiconductor chip comprises a plurality of semiconductor chips those are stacked according to a step-wise structure.
